(19) United States
(12) Patent Application Publication
(10) Pub. No.: US 2025/0076381 A1
(43) Pub. Date: Mar. 6, 2025

(54) RECEIVING CIRCUIT IN TEST DEVICE, TEST SYSTEM HAVING THE SAME, AND OPERATING METHOD THEREOF

(71) Applicant: SAMSUNG ELECTRONICS CO., LTD., SUWON-SI (KR)

(72) Inventors: SEONGKWAN LEE, SUWON-SI (KR); CHEOLMIN PARK, SUWON-SI (KR); MINHO KANG, SUWON-SI (KR); JUNYEON WON, SUWON-SI (KR); JAEMOO CHOI, SUWON-SI (KR)

(21) Appl. No.: 18/583,516

(22) Filed: Feb. 21, 2024

(30) Foreign Application Priority Data
Aug. 30, 2023 (KR) 10-2023-0114733

(51) Int. Cl. G01R 31/319; G01R 31/317

(52) U.S. Cl. CPC G01R 31/31922; G01R 31/31709

(57) ABSTRACT

A receiving circuit of a test device includes a first data sampling circuit that samples a data signal using a first recovery clock, a second data sampling circuit that samples an output signal of the first data sampling circuit using a second recovery clock, and a third data sampling circuit that samples an output signal of the second data sampling circuit using a third recovery clock. The receiving circuit further includes a first clock recovery circuit that receives the data signal and generates the first recovery clock, a second clock recovery circuit that receives the output signal of the first data sampling circuit and generates the second recovery clock, and a third clock recovery circuit that receives the output signal of the second data sampling circuit and generates the third recovery clock.

### CROSS-REFERENCE TO RELATED APPLICATION(S)

This application claims priority under 35 U.S.C. § 119 to Korean Patent Application No. 10-2023-0114733 filed on Aug. 30, 2023 in the Korean Intellectual Property Office, the disclosure of which is incorporated by reference herein in its entirety.

### TECHNICAL FIELD

Embodiments of the present inventive concept relate to a receiving circuit of a test device, a test system having the same, and a method of operating the same.

### DISCUSSION OF RELATED ART

In general, clock data recovery (CDR) may recover a clock signal from a serial data bit stream, and may use the recovered clock signal to synchronously sample data. The CDR may extract the clock signal from the serial data bit stream. This may be mainly done in a manner of detecting transition in a center of the data and generating a clock. The recovered clock signal may be used to sample a data stream at an appropriate timing. Therefore, an operation of converting serial data into parallel data may be performed. A phase of the clock may be dynamically adjusted according to a change in serial data. This may optimize timing of data sampling to minimize or reduce data transmission errors.

### SUMMARY

An aspect of the present inventive concept provides a receiving circuit of a test device, which may reduce high-frequency jitter, a test system having the same, and a method of operating the same.

According to an aspect of the present inventive concept, a receiving circuit of a test device includes a first data sampling circuit that samples a data signal using a first recovery clock, a second data sampling circuit that samples an output signal of the first data sampling circuit using a second recovery clock, and a third data sampling circuit that samples an output signal of the second data sampling circuit using a third recovery clock The receiving circuit further includes a first clock recovery circuit that receives the data signal and generates the first recovery clock, a second clock recovery circuit that receives the output signal of the first data sampling circuit and generates the second recovery clock, and a third clock recovery circuit that receives the output signal of the second data sampling circuit and generates the third recovery clock.

According to an aspect of the present inventive concept, a receiving circuit of a test device includes a plurality of clock data recovery circuits connected in cascade. Each of the plurality of clock data recovery circuits includes a clock recovery circuit that receives a data signal and generates a recovery clock, and a data sampling circuit that samples the data signal in response to the recovery clock.

According to an aspect of the present inventive concept, a test system includes a probe card that contacts pads of a device under test (DUT), a pogo block that receives output signals from the probe card, an interface board that receives output signals from the pogo block, converts the received output signals, and outputs the converted output signals through a cable, and a test device connected to the interface board through the cable that tests the DUT through signals received through the cable. The test device includes a receiving circuit having a plurality of clock data recovery circuits connected in cascade.

### BRIEF DESCRIPTION OF DRAWINGS

The above and other features of the present inventive concept will become more apparent by describing in detail embodiments thereof with reference to the accompanying drawings.

FIG. 1 is a view illustrating a receiving circuit of a general test device.

FIG. 2 is a view illustrating a waveform of output jitter of the receiving circuit illustrated in FIG. 1.

FIG. 3 is a view illustrating a time error at a point in time of converting data in the receiving circuit illustrated in FIG. 1.

FIG. 4 is a view illustrating a receiving circuit of a test device according to an embodiment.

FIG. 5 is a view illustrating a jitter spectrum in each stage of a receiving circuit according to an embodiment.

FIG. 6 is a view illustrating a time error at a point in time of converting data according to timing of a receiving circuit according to an embodiment.

FIG. 7 is a view illustrating a receiving circuit according to an embodiment.

FIG. 8 is a flowchart illustrating a method of operating a receiving circuit according to an embodiment.

FIG. 9 is a view illustrating a test system according to an embodiment.

### DETAILED DESCRIPTION

Embodiments of the present inventive concept will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

The term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art. Further, it is to be understood that while parameters may be described herein as having “about” a certain value, according to embodiments, the parameter may be exactly the certain value or approximately the certain value within a measurement error as would be understood by a person having ordinary skill in the art.

A receiving circuit of a test device according to embodiments of the present inventive concept, a test system having the same, and an operating method thereof may restore the clock of an input signal and sample the signal with the restored clock, thereby converting it into a clean signal with reduced jitter. The receiving circuit, the test system, and the operating method may properly receive data signals without distortion, even if a signal with high-frequency jitter is input, as the first-stage Clock Data Recovery (CDR) follows the rapid fluctuations of the data. Furthermore, embodiments of the present inventive concept may reduce high-frequency jitter not filtered by the first-stage CDR without data distortion through subsequent CDR stages. As a result, embodiments of the present inventive concept may output a clean signal with only low-frequency jitter remaining. The receiving circuit, the test system, and the operating method are usable in environments with severe high-frequency jitter. Also, the receiving circuit, the test system, and the operating method are applicable in wafer tester environments with poor signal quality.

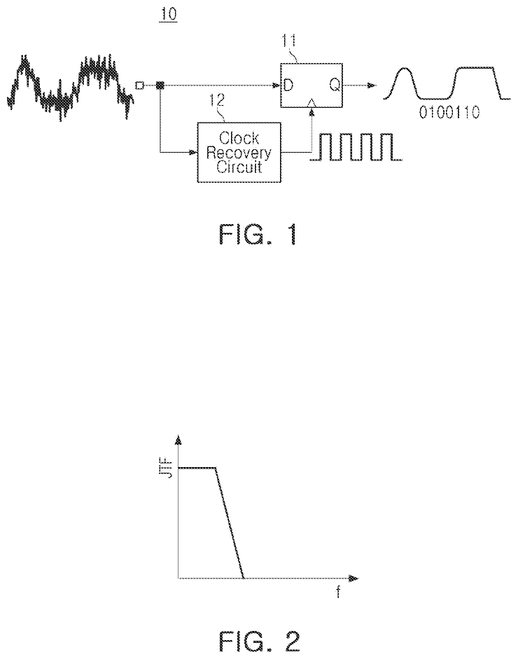

FIG. 1 is a view illustrating a receiving circuit 10 of a general test device. Referring to FIG. 1, a receiving circuit 10 may include a data sampling circuit 11 and a clock recovery circuit 12. The data sampling circuit 11 may output data in response to a recovered clock. The data sampling circuit 11 may be implemented as a flip-flop (e.g., a DQ flip-flop). The clock recovery circuit 12 may generate a recovered clock from received data. The clock recovery circuit 12 may recover an original clock based on clock information embedded in received data stream.

In the receiving circuit 10 illustrated in FIG. 1, the recovered clock may not quickly follow a period change of an input signal (e.g., <about 10 MHz bandwidth (BW)). Therefore, when sampling a signal with the recovered clock, incorrect data may be sampled at a point in time at which a phase of a clock is significantly offset momentarily from a phase of data.

FIG. 2 is a view illustrating a waveform of output jitter of the receiving circuit 10 illustrated in FIG. 1.

Referring to FIG. 2, the receiving circuit 10 may be implemented using only clock data recovery (CDR) having a low bandwidth for minimizing or reducing output jitter, to reduce jitter to be passed through. In a signal having poor signal quality and a lot of high-frequency jitter, all high-frequency jitter may be filtered out in a first stage to stabilize the clock, but may not follow rapid fluctuation of the data. As a result, the data may be corrupted when sampling.

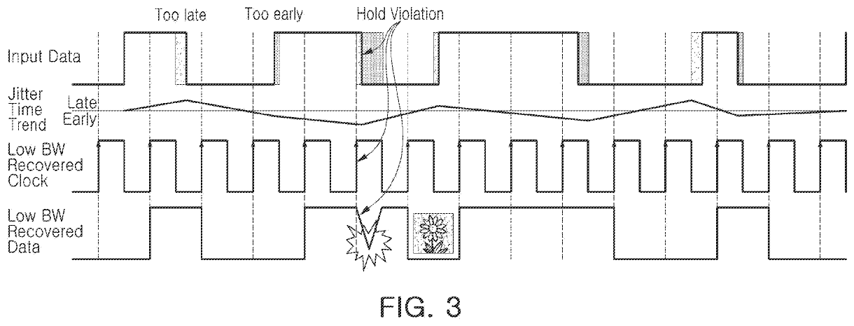

FIG. 3 is a view illustrating a time error at a point in time of converting data in the receiving circuit 10 illustrated in FIG. 1.

Referring to FIG. 3, a recovered clock of the receiving circuit 10 may not quickly follow a change in period of the input signal (e.g., <about 10 MHz BW). Therefore, when sampling the input signal with the recovered clock, incorrect data may be acquired during data sampling at a point in time at which the phase of the clock is significantly offset momentarily from the phase of the data. Therefore, noise may occur in an image received from an image sensor during a test operation. During the test operation, non-defective products may be erroneously classified as defective products, and losses may thus occur.

A receiving circuit according to an embodiment may be implemented with CDR in multiple stages, which may reduce such high-frequency jitter.

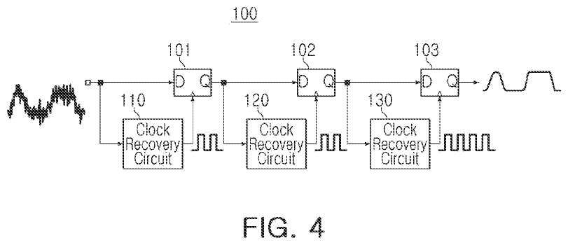

FIG. 4 is a view illustrating a receiving circuit 100 of a test device according to an embodiment.

Referring to FIG. 4, a receiving circuit 100 may include a first data sampling circuit 101, a second data sampling circuit 102, a third data sampling circuit 103, a first clock recovery circuit 110, a second clock recovery circuit 120, and a third clock recovery circuit 130.

The first data sampling circuit 101 may sample an input signal in response to a first recovery clock. In this case, the first recovery clock may be output from the first clock recovery circuit 110. The first data sampling circuit 101 may be implemented as a flip-flop. The second data sampling circuit 102 may sample an output signal of the first data sampling circuit 101 in response to a second recovery clock. In this case, the second recovery clock may be output from the second clock recovery circuit 120. The third data sampling circuit 103 may sample an output signal of the second data sampling circuit 102 in response to a third recovery clock. In this case, the third recovery clock may be output from the third clock recovery circuit 130.

The first clock recovery circuit 110 may receive the input signal and generate the first recovery clock. The second clock recovery circuit 120 may receive the output signal of the first data sampling circuit 101 and generate the second recovery clock. The third clock recovery circuit 130 may receive the output signal of the second data sampling circuit 102 and generate the third recovery clock.

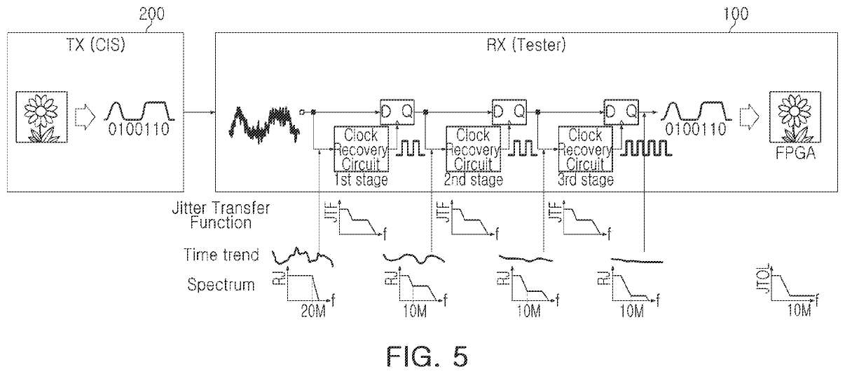

FIG. 5 is a view illustrating a jitter spectrum in each stage of a test system 1000 according to an embodiment.

Referring to FIG. 5, a transmission circuit 200 (TX) of a CMOS image sensor (CIS) may convert a captured image into an electrical signal, and may then transmit only data without separately transmitting a clock signal. In a CIS test operation, a receiving circuit 100 (RX) of a test device may receive an image signal by recovering a clock from a data signal received from an image sensor and then sampling the data signal using the recovered clock. In an embodiment, in a jitter-free signal under a semiconductor facility environment, data conversion may occur at a falling edge of a clock. In an embodiment, in a jittery signal under the semiconductor facility environment, data conversion may occur at a point in time, faster or slower than the falling edge of the clock.

The receiving circuit 100 that receives a signal from a test facility may be implemented as an FPGA. In an embodiment, the receiving circuit 100 may normally receive random jitter of about 10 MHz BW or less. For example, the receiving circuit 100 may eliminate high-frequency jitter between about 10 MHz and about 20 MHz. The receiving circuit 100 may implement CDR in multiple stages to eliminate about 30% to about 70% of the high-frequency jitter between about 10 MHz and about 20 MHz.

In an embodiment, the data signal includes random jitter of a predetermined bandwidth. The predetermined bandwidth may be about 10 MHz to about 20 MHz. An output signal of the first data sampling circuit 101 may have about ½ random jitter of the random jitter, an output of the second data sampling circuit 102 may have about ¼ random jitter of the random jitter, and an output of the third data sampling circuit 103 may have about ⅛ random jitter of the random jitter.

For example, as illustrated in FIG. 5, the receiving circuit 100 may be implemented with CDR having three stages. Each stage of the CDR may reduce about 10 MHz to about 20 MHz jitter by about ½. Therefore, the receiving circuit 100 implemented with CDR having three stages may reduce the about 10 MHz to about 20 MHz jitter by about ⅛. As a result, the signal that may be received by the FPGA of the test facility may be generated.

Even when a data signal having high-frequency jitter is input from the transmission circuit 200 of the image sensor (CIS), a receiving circuit 100 according to an embodiment may receive the data signal normally without distortion, as CDR in a first stage follows rapid fluctuation of data. The high-frequency jitter that may not be filtered out in the first stage may be reduced by CDR in the next stage, without data distortion, to ultimately generate a clean signal with only low-frequency jitter remaining. Therefore, the receiving circuit 100 of embodiments of the present inventive concept may be used in an environment having severe high-frequency jitter regardless of power consumption and a chip size.

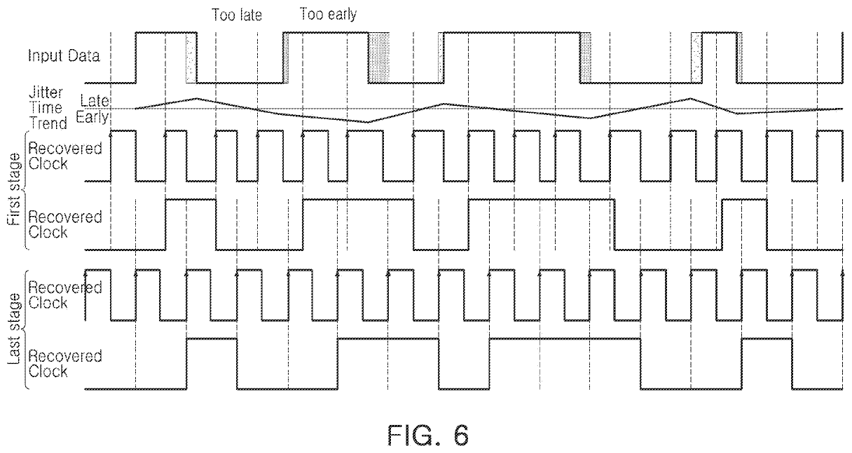

FIG. 6 is a view illustrating a time error at a point in time of converting data according to timing of a receiving circuit 100 according to an embodiment.

As illustrated in FIG. 6, a recovered clock generated in a first stage may follow rapid fluctuation of an input signal. A signal passing through the first stage may have no data distortion, but may have a large amount of jitter. The recovered clock generated in the last stage may not respond to the rapid fluctuation in the input signal, and a stable signal passing through the last stage may have a small amount of jitter. As a result, a high-quality clock may be output.

In FIGS. 4 to 6, the receiving circuit 100 is implemented with CDR having three stages, but it should be understood that a stage of CDR of the present inventive concept is not limited thereto. For example, the receiving circuit according to embodiments of the present inventive concept may be implemented with CDR having two or more stages.

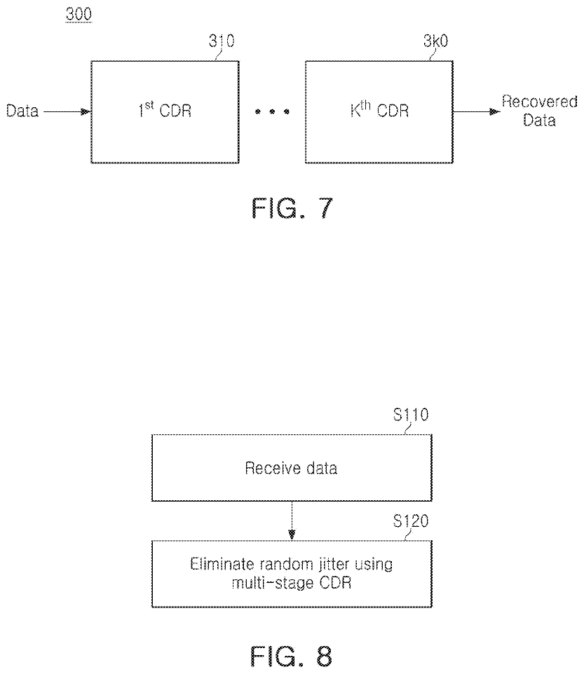

FIG. 7 is a view illustrating a receiving circuit 300 according to an embodiment. Referring to FIG. 7, a receiving circuit 300 may include a first clock data recovery circuit 310 to a k^{th} clock data recovery circuit 3k0, connected in cascade. In this case, k may be an integer equal to or greater than 2. In an embodiment, each of the clock data recovery circuits 310 to 3k0 may be implemented as a data sampling circuit and a clock recovery circuit, as illustrated in FIG. 4. The clock recovery circuit may be implemented as a phase locked loop (PLL) structure or a delay locked loop (DLL) structure.

In an embodiment, the clock data recovery circuits 310 to 3k0 connected in cascade may reduce random jitter having a predetermined frequency band in a stepwise manner. In an embodiment, the first clock data recovery circuit 310, among the clock data recovery circuits 310 to 3k0, may reduce high-frequency random jitter by about ½. In an embodiment, the predetermined frequency band may be about 10 MHz to about 20 MHz.

In an embodiment, the first clock data recovery circuit 310 to the k^{th} clock data recovery circuit 3k0 may include an edge extraction circuit that generates a plurality of edge data based on logical values of bits included in a plurality of sampling data, an edge integration circuit that performs a logical operation between the plurality of edge data to generate integrated edge data, and a filter circuit that filters the integrated edge data to recover clock data, respectively.

A receiving circuit according to an embodiment may include a circuit that eliminates jitter by a multi-stage CDR circuit for transmitting a signal containing high-bandwidth jitter to a receiving system allowing only low-bandwidth jitter. The multi-stage CDR circuit may pass jitter having a bandwidth allowed by the receiving system, and only a certain portion of jitter having a bandwidth not allowed by the receiving system may be attenuated to prevent a data error.

FIG. 8 is a flowchart illustrating a method of operating a receiving circuit of a test device according to an embodiment. Referring to FIGS. 4 to 8, a receiving circuit of a test device may operate as follows.

The receiving circuit 100 (see FIG. 4) of the test device may receive image data without a clock from an external device (S110). The receiving circuit 100 may receive the image data, and eliminate random jitter of a predetermined bandwidth using a multi-stage CDR circuit (S120).

In an embodiment, the multi-stage CDR circuit may include a plurality of data sampling circuits, and a plurality of clock recovery circuits that provide recovery clocks for sampling the image data to each of the plurality of data sampling circuits. In this case, each of the plurality of data sampling circuits may be implemented as a flip-flop. In an embodiment, received image data may include random jitter of a predetermined bandwidth, and each of the plurality of data sampling circuits may reduce received random jitter by about ½. In an embodiment, the predetermined bandwidth may be about 10 MHz to about 20 MHz.

In an embodiment, a first data sampling circuit, among the plurality of data sampling circuits, may output data having jitter equal to or greater than a predetermined frequency, and remaining consecutive data sampling circuits may reduce the jitter in a stepwise manner. In an embodiment, the receiving circuit may be implemented as a field programmable gate array (FPGA). In an embodiment, the received image data may be transmitted from the external device without a clock. For example, image data may be received from an image sensor at a wafer level. In an embodiment, the receiving circuit may only allow random jitter of about 10 MHz or less. In an embodiment, a test operation may be performed at speeds equal to or greater than about 13 Gbps in a test device.

A receiving circuit of a test device and a method of operating the same, according to an embodiment, may use the multi-stage CDR circuit, such that a CDR bandwidth may be large, but output jitter may be relatively small.

A receiving circuit according to an embodiment may be applicable to a semiconductor test facility.

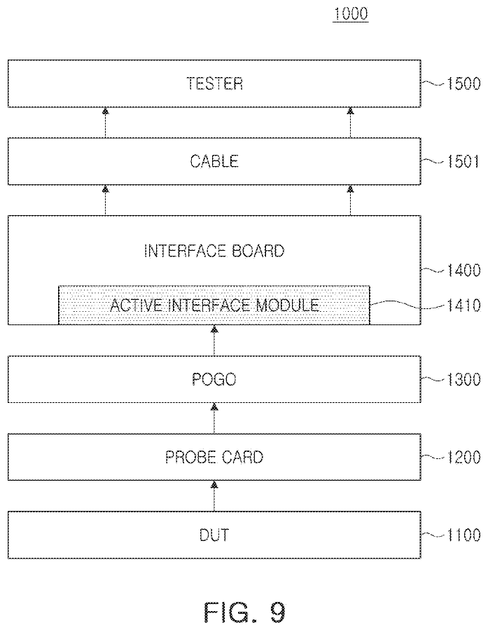

FIG. 9 is a view illustrating a test system 1000 according to an embodiment.

Referring to FIG. 9, a test system 1000 may include a probe card 1200, a pogo block (POGO) 1300, an interface board 1400, and a test device (ATM) 1500.

The probe card 1200 may perform a test process to test electrical characteristics of a device under test (DUT). For example, the probe card 1200 may apply an electrical signal to image sensors formed on a wafer and perform an electric die sorting (EDS) process for determining whether the image sensors are defective by signals output from the image sensors in response to the applied electrical signal. Additionally, the probe card 1200 may be applied to any test process to test whether a plurality of image sensors are defective. For example, the probe card 1200 may apply an electrical signal provided from the test device 1500, for example, at least one of power or a signal, to a wafer including the plurality of image sensors, and may output a signal, output in response to the applied electrical signal, to the test device 1500. While a test process is in progress, a probe pin may physically contact a pad on the wafer, to transmit the electrical signal to the wafer or receive the signal output from the wafer. At least a portion of the probe pin may be an input probe pin used to transmit the electrical signal provided from the test device 1500 to the wafer. Additionally, at least a portion of the probe pin may be an output probe pin used to receive the electrical signal output from the wafer. These probe pins may also be referred to as probe needles or probes. In an embodiment, the probe card 1200 may be, for example, a cantilever probe card, a vertical probe card, or a membrane probe card, or the probe card 1200 may be, for example, a micro-electromechanical systems (MEMS) probe card.

The pogo block (POGO) 1300 may include a plurality of pins used to connect the probe card 1200 and the interface board 1400. In this case, each of the plurality of pins may include a POGO pin.

The interface board 1400 may map the probe card 1200 and the test device 1500. Additionally, the interface board 1400 may include an active interface module 1410. The active interface module 1410 may be implemented in response to communication standards of the DUT 1100. In an embodiment, the active interface module 1410 may be implemented in a modular manner to be inserted into the interface board 1400 through a module connector. For example, the active interface module 1410 may be suitably implemented as any one of a mobile industry processor interface (MIPI) C-PHY, an MIPI D-PHY, an MIPI M-PHY, or an MIPI A-PHY. The MIPI may be a serial interface that connects hardware and software between a processor and peripheral devices. The active interface module 1410 according to embodiments of the present inventive concept is not limited to the above-described MIPI standards. The active interface module 1410 according to embodiments of the present inventive concept may perform communication according to any type of communication interface corresponding to serial interface standards output from a CMOS image sensor. The active interface module 1410 may receive data from the image sensor using a multi-stage clock data recovery circuit, as described with reference to FIGS. 1 to 8.

The test device 1500 may transmit an input signal and a control signal to at least one image sensor through the probe card 1200. The test device 1500 may simultaneously test the DUT 1100. In this case, the DUT 1100 may include a wafer having a plurality of image sensors. In an embodiment, the test device 1500 may be connected to the interface board 1400 through a cable 1501. Additionally, the test device 150 may receive the data from the image sensor using a multi-stage clock data recovery circuit, as described with reference to FIGS. 1 to 8.

To receive a high-speed signal, a test system 1000 according to an embodiment may locate the active interface module 1410, which receives the high-speed signal, closest to the wafer (e.g., the DUT 1100). In general, a high-speed signal utilizes a small length and a short contact structure to reduce loss. As a signal speed increases, signal loss may occur between the pogo block 1300 and the interface board 1400. In an embodiment, the active interface module 1410 may include a signal compensation circuit that compensates for loss between the wafer (e.g., the DUT 1100) and the probe card 1200 and loss between the pogo block 1300 and the interface board 1400. In an embodiment, the active interface module 1410 may include a long-distance signal generation circuit that changes to a differential signal level that may be advantageous for long-distance without a change in frequency speed. In an embodiment, the active interface module 1410 may include a standard response circuit that may respond even if the interface output from the wafer (e.g., the DUT 1100) may be changed. The active interface module 1410 may modularize the signal compensation circuit, the long-distance signal generation circuit, and the standard response circuit, described above.

The devices described above may be implemented with a hardware component, a software component, and/or a combination of the hardware component and the software component. For example, the devices and components described in embodiments may be implemented using a processor, a controller, an arithmetic logic unit (ALU), a digital signal processor, a microcomputer, a field programmable gate array (FPGA), a programmable logic unit (PLU), or one or more general-purpose or special-purpose computers, such as any other device capable of executing and responding to an instruction. A processing device may execute an operating system (OS) and one or more software applications running on the operating system. Additionally, the processing device may access, store, manipulate, process, and generate data in response to execution of software. For ease of understanding, although the processing device is described as being used as a single processing device, those skilled in the art will understand that the processing device may include multiple processing elements or multiple types of processing elements. For example, the processing device may include a plurality of processors or one processor, and one controller. Additionally, other processing configurations, such as, for example, parallel processors, may be utilized.

Software may include a computer program, a code, an instruction, or a combination of one or more of a computer program, code, or instruction, and may configure a processing unit to operate as desired, or may independently or collectively control a processing device. The software and/or data may be embodied in any type of, for example, machine, component, physical device, virtual equipment, computer storage medium or device, to be interpreted by or to provide instructions or data to a processing device. The software may be distributed over networked computer systems, and may be stored or executed in a distributed manner. The software and data may be stored on one or more computer-readable recording media.

A receiving circuit of a test device, a test system having the same, and a method of operating the same, according to an embodiment, may reduce high-frequency jitter in a stepwise manner using a multi-stage clock recovery circuit.

While the present inventive concept has been particularly shown and described with reference to embodiments thereof, it will be understood by those of ordinary skill in the art that various changes in form and detail may be made therein without departing from the spirit and scope of the present inventive concept as defined by the following claims.

What is claimed is:

1. A test device comprising a receiving circuit,
wherein the receiving circuit includes:
a first data sampling circuit configured to sample a data signal using a first recovery clock;
a second data sampling circuit configured to sample an output signal of the first data sampling circuit using a second recovery clock;
a third data sampling circuit configured to sample an output signal of the second data sampling circuit using a third recovery clock;
a first clock recovery circuit configured to receive the data signal and generate the first recovery clock;
a second clock recovery circuit configured to receive the output signal of the first data sampling circuit and generate the second recovery clock; and
a third clock recovery circuit configured to receive the output signal of the second data sampling circuit and generate the third recovery clock.

2. The test device of claim 1, wherein each of the first data sampling circuit, the second data sampling circuit, and the third data sampling circuit includes a flip-flop.

3. The test device of claim 1, wherein the data signal includes random jitter of a predetermined bandwidth,
wherein the output signal of the first data sampling circuit has about ½ random jitter of the random jitter,
the output signal of the second data sampling circuit has about ¼ random jitter of the random jitter, and
an output signal of the third data sampling circuit has about ⅛ random jitter of the random jitter.

4. The test device of claim 3, wherein the predetermined bandwidth is about 10 MHz to about 20 MHz.

5. The test device of claim 1, wherein the output signal of the first data sampling circuit includes jitter at or above a predetermined frequency,
wherein the output signal of the second data sampling circuit and an output signal of the third data sampling circuit reduce the jitter.

6. The test device of claim 1, wherein the receiving circuit is implemented with a field programmable gate array (FPGA).

7. The test device of claim 1, wherein the data signal is transmitted without a clock.

8. The test device of claim 1, wherein the data signal is received from an image sensor at a wafer level.

9. The test device of claim 1, wherein the receiving circuit allows random jitter of about 10 MHz or less.

10. The test device of claim 1, wherein a test operation is performed in the test device at a speed of about 13 Gbps or more.

11. A test device comprising a receiving circuit,
wherein the receiving circuit includes:
a plurality of clock data recovery circuits connected in cascade,
wherein each of the plurality of clock data recovery circuits includes:
a clock recovery circuit configured to receive a data signal and generate a recovery clock; and
a data sampling circuit configured to sample the data signal in response to the recovery clock.

12. The test device of claim 11, wherein the plurality of clock data recovery circuits reduces random jitter having a predetermined frequency band in a stepwise manner.

13. The test device of claim 12, wherein a first clock data recovery circuit, among the plurality of clock data recovery circuits, reduces the random jitter by about ½.

14. The test device of claim 12, wherein the predetermined frequency band is about 10 MHz to about 20 MHz.

15. The test device of claim 11, wherein the data signal is received from an image sensor without a clock.

16. A test device of claim 1,
wherein the test device connected to an interface board through a cable and configured to test a device under test (DUT) through signals received through the cable,
wherein the receiving circuit having a plurality of clock data recovery circuits connected in cascade.

17. The test device of claim 16, wherein the receiving circuit reduces random jitter having a predetermined frequency band in a stepwise manner.

18. The test device of claim 17, wherein the predetermined frequency band is about 10 MHz to about 20 MHz.

19. The test device of claim 16, wherein the test device performs a test operation at a speed of about 13 Gbps or more.

20. The test device of claim 16, wherein the DUT comprises an image sensor.
